(19) United States
(12) Patent Application Publication
(10) Pub. No.: US 2026/0114299 A1
(43) Pub. Date: Apr. 23, 2026

(54) MULTI-CHIPLET SEMICONDUCTOR DEVICE WITH REDUNDANT DATA LINE

(71) Applicant: Silicon Storage Technology, Inc., San Jose, CA (US)

(72) Inventors: Derkant Cheng, Taipei City (TW); TING-HAO CHANG, Zhubei (CN); FENG ZHOU, Fremont, CA (US); LORENZO BEDARIDA, Vimercate (IT); SIMONE BARTOLI, Lecco (IT); SHIJUN QI, Shanghai (CN); FRANCIS LIU, Qing xuanzé xiàn shì (TW); CHAO-YU LIU, Taoyuan City (TW)

(21) Appl. No.: 19/023,215

(22) Filed: Jan. 15, 2025

(30) Foreign Application Priority Data
Oct. 17, 2024 (CN) 202411457453.7

(51) Int. Cl. H01L 23/538; H01L 23/00; H01L 25/065

(52) U.S. Cl. CPC H10W 70/611; H10W 70/635; H10W 70/641; H10W 90/00; H10W 90/22; H10W 90/792; H10W 90/794

(57) ABSTRACT

A semiconductor device includes an interface between first and second chiplets that comprises data lines and a redundant data line. The first and second chiplets include input/output modules each electrically coupled to one of the data lines. Each input/output module of the first chiplet is configured to send data over its corresponding data line to the corresponding input/output module of the second chiplet. In the case of a faulty data line, the corresponding one input/output module can reroute its data to a second input/output module for transmission over its data line, and the second input/output module can reroute its data to a third input/output module for transmission over its data line, and so on, until the last input/output module can reroute its data to the redundant data line for transmission over the redundant data line.

### RELATED APPLICATION

This application claims the benefit of Chinese Patent Application No. 202411457453.7, filed on Oct. 17, 2024.

### FIELD OF INVENTION

The present disclosure relates to multi-chiplet semiconductor devices.

### BACKGROUND OF THE INVENTION

A multi-chiplet semiconductor device is one that includes multiple chiplets (also referred to as chips or die) in a single package, where the package includes one or more interfaces that electrically connect (also referred to herein interchangeably as electrically couple) the chiplets to each other. Common interfaces can include interposers such as RDL (redistribution layer) interposers and silicon interposers, as well as hybrid bonding. Complex chiplet systems can include hundreds or even thousands of electrical connections between the chiplets.

One issue with complex chiplet systems can be the difficulty of reliably establishing all the desired electrical connections between the chiplets. Specifically, in forming the interface, one or more of the electrical connections could be faulty (i.e., an electrical connection includes an electrical open, an electrical short to ground, an electrical short to a power line, an electrical short to another electrical connection, etc.). When a critical electrical connection is found to be faulty, the entire multi-chiplet semiconductor device may have to be discarded as defective, thereby reducing yield and reliability, and increasing manufacturing costs. Also, given the high number of electrical connections, testing all the electrical connections can be complex and time consuming.

There is a need for a reliable testing protocol, and the ability for effectively repairing chiplet electrical connections without discarding the multi-chiplet semiconductor device as defective when a defective electrical connection is found.

### BRIEF SUMMARY OF THE INVENTION

The aforementioned problems and needs are addressed by a semiconductor device that comprises:
a first chiplet;
a second chiplet;
an interface between the first chiplet and the second chiplet, wherein the interface comprises data lines and a redundant data line between the first chiplet and the second chiplet;
the second chiplet comprises a first input/output module and a second input/output module, wherein:
   the first input/output module is electrically coupled to a first of the data lines and to the second input/output module, and the first input/output module is configured to receive first data and to send the first data to the second input/output module, and
   the second input/output module is electrically coupled to a second of the data lines and to the redundant data line, the second input/output module is configured to receive second data and to send the second data to the redundant data line, and to receive the first data from the first input/output module and to send the first data to the second of the data lines; and
the first chiplet comprises a third input/output module and a fourth input/output module, wherein:
   the third input/output module is electrically coupled to the second of the data lines and to the redundant data line and to the fourth input/output module, the third input/output module is configured to receive the second data from the redundant data line, and to receive the first data from the second of the data lines and to send the first data to the fourth input/output module, and
   the fourth input/output module is electrically coupled to the first of the data lines, and the fourth input/output module is configured to receive the first data from the third input/output module.

A method of sending first data and second data in a semiconductor device that comprises:
a first chiplet;
a second chiplet;
an interface between the first chiplet and the second chiplet, wherein the interface comprises data lines and a redundant data line between the first chiplet and the second chiplet;
the second chiplet comprises a first input/output module and a second input/output module, wherein:
   the first input/output module is electrically coupled to a first of the data lines and to the second input/output module, and
   the second input/output module is electrically coupled to a second of the data lines and to the redundant data line;
the first chiplet comprises a third input/output module and a fourth input/output module, wherein:
   the third input/output module is electrically coupled to the second of the data lines and to the redundant data line and to the fourth input/output module, and
   the fourth input/output module is electrically coupled to the first of the data lines;
the method comprises:
   receiving first data by the first input/output module;
   sending the first data from the first input/output module to the second input/output module;
   receiving the first data by the second input/output module;
   sending the first data from the second input/output module to the second of the data lines;
   receiving second data by the second input/output module;
   sending the second data from the second input/output module to the redundant data line;
   receiving the second data by the third input/output module from the redundant data line;
   receiving the first data by the third input/output module from the second of the data lines; and
   sending the first data from the third input/output module to the fourth input/output module.

Other objects and features of the present disclosure will become apparent by a review of the specification, claims and appended figures.

### BRIEF DESCRIPTION OF THE DRAWINGS

FIG. 1 is a side cross sectional view of a multi-chiplet semiconductor device with an RDL interposer interface.

FIG. 2 is a side cross sectional view of a multi-chiplet semiconductor device with a silicon interposer interface.

FIG. 3 is a side cross sectional view of a multi-chiplet semiconductor device with a hybrid bonding interface.

FIG. 4 is a graphic illustration of data routed through the data lines between two chiplets, where there are no faulty data lines.

FIG. 5 is a graphic illustration of data routed through the data lines between two chiplets, where data is rerouted to avoid a faulty data line that includes a break.

FIG. 6 is a graphic illustration of data routed through the data lines between two chiplets, where data is rerouted to avoid a faulty data line that is shorted to ground.

FIG. 7 is a graphic illustration of data routed through the data lines between two chiplets, where data is rerouted to avoid a faulty data line that is shorted to a power supply voltage Vcc.

FIG. 8 is a graphic illustration of data routed through the data lines between two chiplets, where data is rerouted to avoid a faulty data line that is shorted to another data line.

FIG. 9 is a schematic illustration of the circuitry configuration of the interface modules of the chiplets configured for rerouting of data in the event a data line is faulty.

FIG. 10 is a schematic illustration of the data paths D1-D4 in the event that no data lines are faulty.

FIG. 11 is a schematic illustration of the data paths D1-D4 in the event that data line DL2 is faulty.

FIG. 12 is a schematic illustration of the data paths D1-D4 in the event that data line DL3 is faulty.

FIG. 13 is a schematic illustration of the data paths D1-D4 in the event that data line DL4 is faulty.

FIG. 14 is a simplified schematic illustration of circuitry configuration of FIG. 9, including master control circuitry.

FIG. 15 is a graphic illustration of data routed through the data lines between two chiplets, where data is rerouted to avoid two faulty data lines using two redundant data lines.

### DETAILED DESCRIPTION OF THE INVENTION

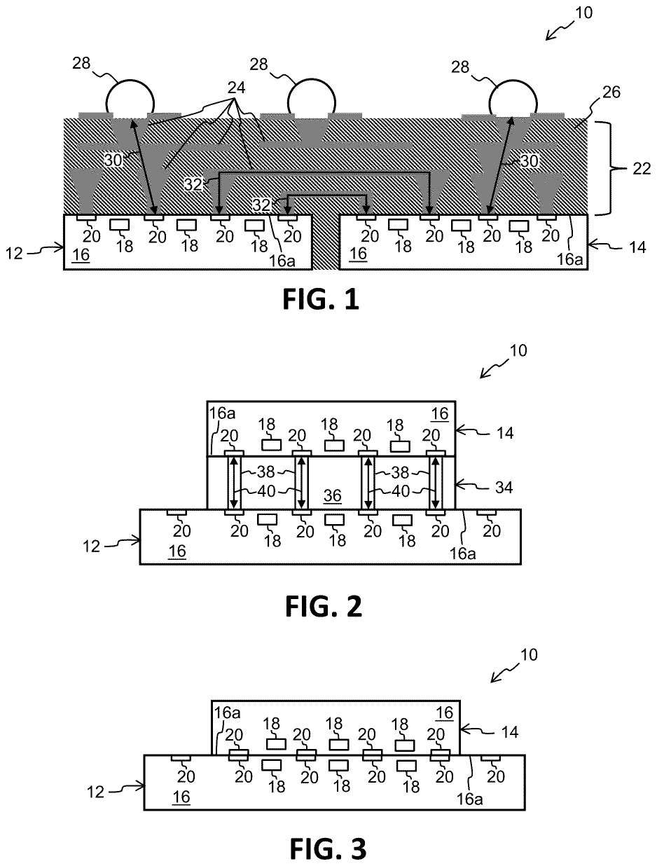

FIG. 1 illustrates a semiconductor device with chiplets electrically connected by an RDL interposer interface. Specifically, the semiconductor device 10 include a first chiplet 12 and a second chiplet 14. Each chiplet 12, 14 includes a substrate 16 (e.g., of semiconductor material such as silicon), and electrical devices 18 (e.g., MOSFET devices) formed on or in the substrate 16 that are electrically connected to contact pads 20 disposed at an active surface 16a of substrate 16. The chiplets 12, 14 are electrically connected to each other by RDL (redistribution layer) interposer interface 22, which includes conductive wiring 24 (e.g., copper) extending through insulation material 26 (e.g., polyimide). The conductive wiring 24 includes a plurality of interconnected segments, some extend horizontally while others extend vertically. Respective portions of conductive wiring 24 are in electrical contact with contact pads 20, with some portions of conductive wiring 24 terminating at the top of the insulation material 26. Contacts 28 (e.g., solder balls) can be formed at the top of the insulation material 26 and in electrical contact with the respective portions of conductive wiring 24, as shown in FIG. 1.

The conductive wiring 24 forms a plurality of conductive paths 30 between selected ones of the contact pads 20 and selected ones of the contacts 28. The conductive wiring 24 also forms a plurality of conductive paths 32 between selected ones of the contact pads 20 of first chiplet 12 and selected ones of the contact pads 20 of second chiplet 14. The conductive paths 30 and 32 extend through insulation material 26. The insulation material 26 also serves to secure the first and second chiplets 12, 14 together as a single packaged semiconductor device 10. The chiplets 12, 14 are disposed side by side in FIG. 1. However, the chiplets 12, 14 could be stacked vertically one over the other with RDL interposer interface 22 therebetween. Further, while only two chiplets 12, 14 are shown in FIG. 1, the semiconductor device 10 can include more than two interconnected chiplets in a single packaged unit.

FIG. 2 illustrates a semiconductor device 10 with chiplets 12, 14 electrically connected by a silicon interposer interface 34. The silicon interposer interface 34 includes a silicon substrate 36, and electrical contacts 38 that extend through the silicon substrate 36. The chiplets 12, 14 are mounted to opposing surfaces of the silicon substrate 36, so that contact pads 20 are in electrical contact with electrical contacts 38. The electrical contacts 38 provide conductive paths 40 between selected contact pads 20 of chiplet 12 and selected contact pads 20 of chiplet 14. The silicon interposer interface 34 also serves to secure the first and second chiplets 12, 14 together as a single packaged semiconductor device 10. Selected contact pads 20 of one or both of chiplets 12, 14 can be left exposed by silicon interposer 34 for off package electrical connections. While only two chiplets 12, 14 are shown in FIG. 2, the semiconductor device 10 can include more than two interconnected chiplets in a single packaged unit.

FIG. 3 illustrates a semiconductor device 10 with chiplets 12, 14 electrically connected using a hybrid bonding interface. The active surfaces 16a of chiplets 12, 14 are mounted to each other by hybrid bonding so that selected contact pads 20 of chiplet 12 are in physical contact (and therefore in electrical contact) with selected contact pads 20 of chiplet 14. The hybrid bonding also serves to secure the first and second chiplets 12, 14 together as a single packaged semiconductor device 10. Selected contact pads 20 of one or both of chiplets 12, 14 can be left exposed by hybrid bonding for off package electrical connections. While only two chiplets 12, 14 are shown in FIG. 3, the semiconductor device 10 can include more than two interconnected chiplets in a single packaged unit.

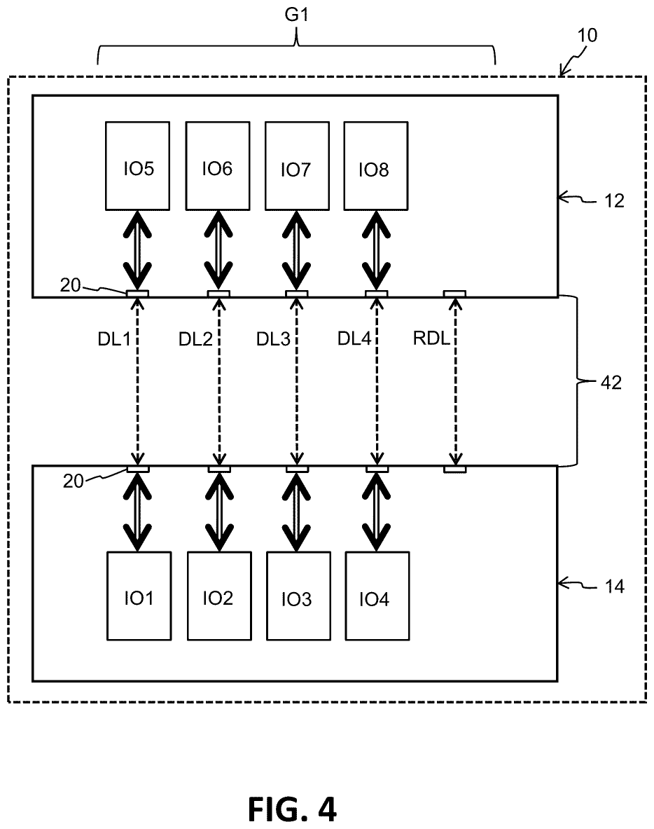

FIG. 4 illustrates the data lines DL created by the interface 42 between chiplets 12 and 14. Interface 42 can include an interposer (e.g., RDL interposer 22 or silicon interposer 34 described above with respect to FIGS. 1 and 2 respectively), hybrid bonding with contact pads 20 of different chiplets in direct contact as describe above with respect to FIG. 3, or any other appropriate connection configuration (e.g., wire bonding or printed circuit boards) that provides electrical connections between contact pads 20 of different chiplets, where those electrical connections form data lines DL that will carry data between chiplets. In the case of interposers, the data lines DL of the interface 42 include the conductive wiring or paths that convey electrical signals from one chiplet to another, as well as the contact pads 20 electrically connected to the respective conductive wiring or paths. In the case of hybrid bonding, the data lines DL of the interface 42 comprise the contact pads 20 in physical contact with each other (i.e., the interface 42 can include components formed on or in the chiplets 12 and 14).

Chiplets 12, 14 each include input/output modules IO. Each input/output module IO is electrically connected to (also referred to herein interchangeably as electrically coupled to), one of the data lines DL and one of the other input/output modules IO. Each input/output module IO is responsible for sending data to, or receiving data from, one of the data lines DL or one of the other input/output modules IO. In the example shown in FIG. 4, there are four input/output modules IO (IO1, IO2, IO3, IO4) in second chiplet 14, four input/output modules IO (IO5, IO6, IO7, IO8) in first chiplet 12, and four data lines DL (DL1, DL2, DL3, DL4). Input/output modules IO1 and IO5 of second and first chiplets 14 and 12 respectively send data to or receive data from the data line DL1, input/output modules IO2 and IO6 of second and first chiplets 14 and 12 respectively send data to or receive data from data line DL2, and so on. Data can include any inter-chiplet electrical signal. While four data lines DL1-DL4, and four associated input/output modules IO in each chiplet 12, 14, are shown, many more data lines DL and associated input/output modules IO can be included. While data lines DL are shown as bidirectional, the input/output modules IO connected to any given data line DL could be configured to send data in only one direction on the data line DL (e.g., input/output module IO1 in second chiplet 14 could be configured to only send data on data line DL1, and input/output module IO5 in first chiplet 12 could be configured to only receive data from data line DL1).

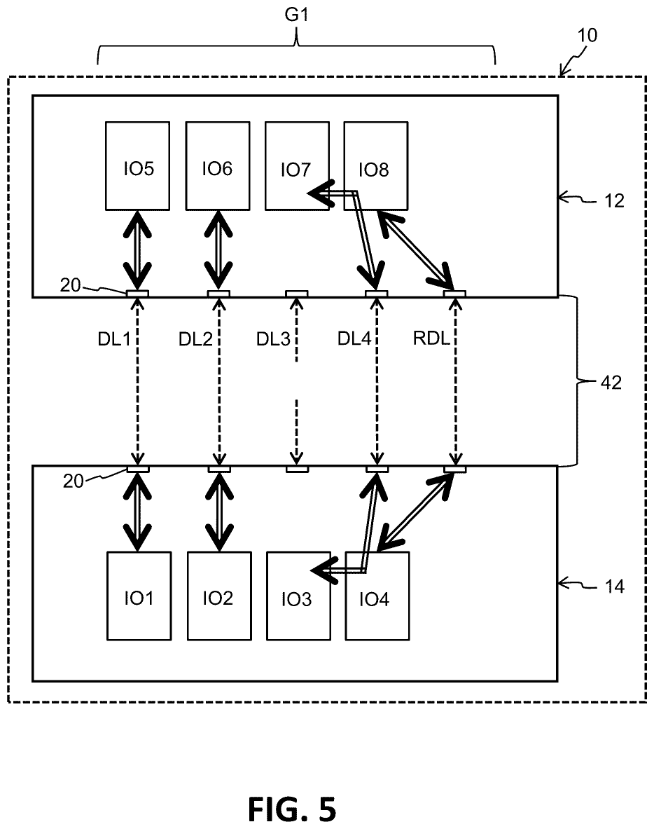

Interface 42 also includes a redundant data line RDL for use when one of the data lines DL is determined to be faulty. FIG. 5 shows an example where data line DL3 is faulty for including a break (i.e., the current path through the data line DL3 is interrupted or “opened” at some point preventing electrical signals from traversing data line DL3). As a result, input/output modules IO3 and IO7 in both chiplets 14 and 12 respectively utilize data line DL4 instead of faulty data line DL3 (e.g., by rerouting data through input/output modules IO4 and IO8 and data line DL4). In turn, input/output modules IO4 and IO8 in chiplets 14 and 12 respectively utilize redundant data line RDL instead of data line DL4. By rerouting data from faulty data line DL3 to data line DL4, and from data line DL4 to redundant data line RDL, communications between chiplets 12, 14 are preserved even though data line DL3 is faulty and unusable.

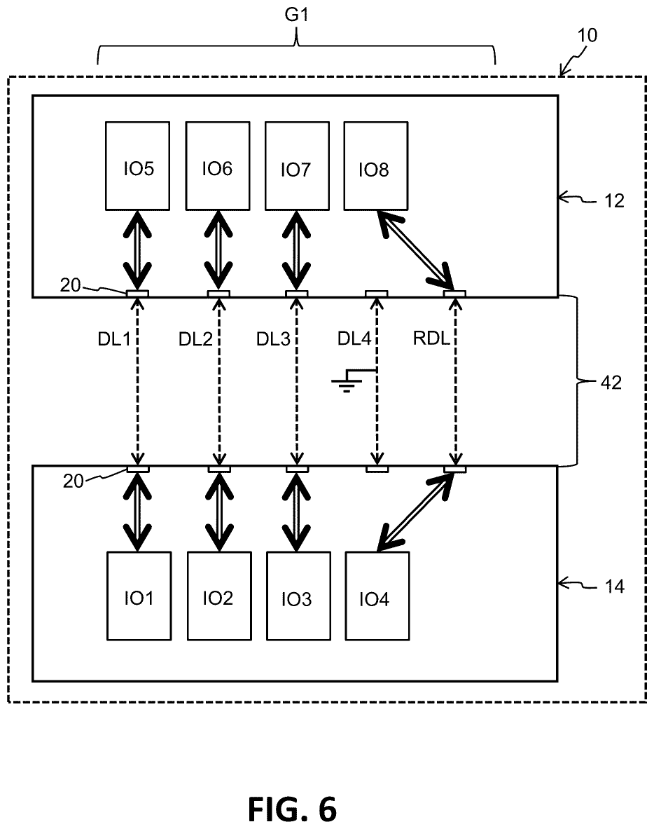

FIG. 6 shows an example where data line DL4 is faulty because it is shorted to ground. As a result, input/output modules IO4 and IO8 in chiplets 14 and 12 respectively utilize redundant data line RDL instead of faulty data line DL4. By rerouting data from faulty data line DL4 to redundant data line RDL, communications between chiplets 12, 14 are preserved even though data line DL4 is faulty and unusable.

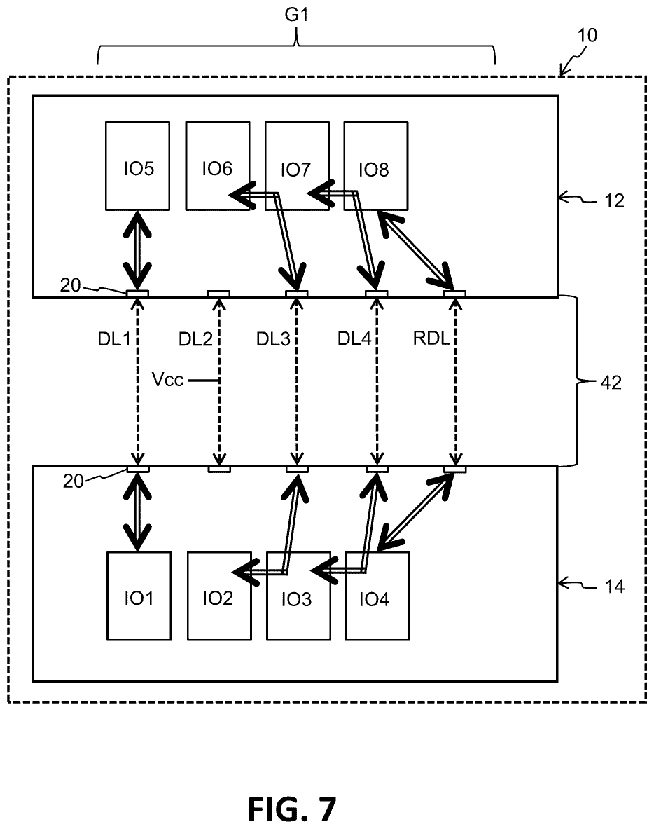

FIG. 7 shows an example where data line DL2 is faulty because it is shorted to power supply voltage Vcc. As a result, input/output modules IO2 and IO6 in chiplets 14 and 12 respectively utilize data line DL3 instead of faulty data line DL2. In turn, input/output modules IO3 and IO7 in chiplets 14 and 12 respectively utilize data line DL4 instead of data line DL3, and input/output modules IO4 and IO8 in chiplets 14 and 12 respectively utilize redundant data line RDL instead of data line DL4. By rerouting data from data line DL2 to data line DL3, from data line DL3 to data line DL4, and from data line DL4 to redundant data line RDL, communications between chiplets 12, 14 are preserved even though data line DL2 is faulty and unusable.

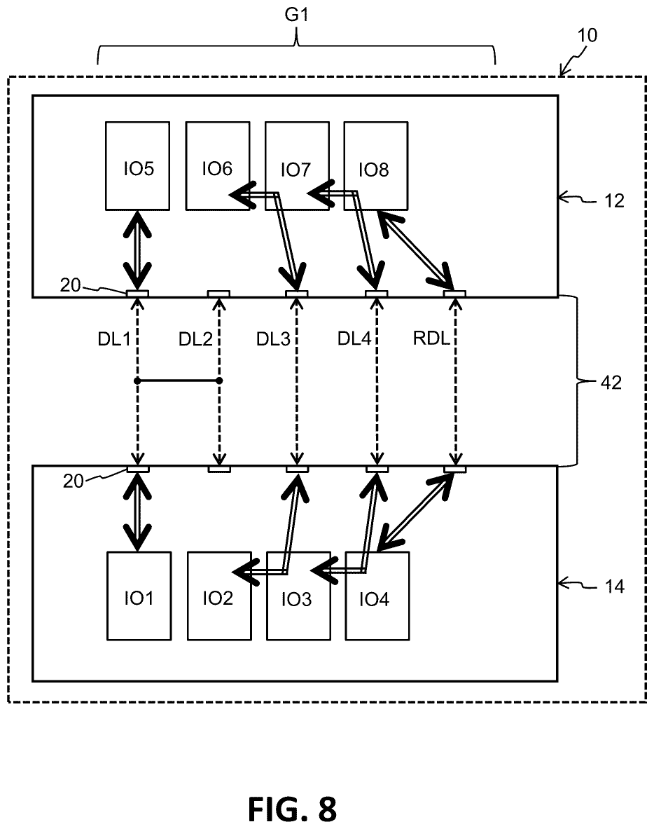

FIG. 8 shows an example where data lines DL1 and DL2 are shorted together. As a result, input/output modules IO1 and IO5 in chiplets 14 and 12 respectively can still utilize data line DL1. However, input/output modules IO2 and IO6 in chiplets 14 and 12 respectively utilize data line DL3 instead of faulty data line DL2. In turn, input/output modules IO3 and IO7 in chiplets 14 and 12 respectively utilize data line DL4 instead of data line DL3, and input/output modules IO4 and IO8 in chiplets 14 and 12 respectively utilize redundant data line RDL instead of data line DL4. By rerouting data from data line DL2 to data line DL3, from data line DL3 to data line DL4, and from data line DL4 to redundant data line RDL, communications between chiplets 12, 14 are preserved even though data line DL2 is faulty and unusable.

Given the large numbers of data lines DL that can be used between chiplets 12, 14, the data lines DL and their associated input/output modules IO can be divided up in groups, where each group of data lines DL and their associated input/output modules IO includes an associated redundant data line RDL for use by the group should any of the data lines DL for that group be faulty. For example, FIGS. 4-8 illustrate a group G1 that includes of four data lines DL (DL1-DL4), four input/output modules IO (IO1-IO4) in second chiplet 14, four input/output modules IO (IO5-IO8) in first chiplet 12, and one redundant data line RDL. The number of data lines DL and associated input/output module IO in each group G can vary (i.e., can be greater or fewer than 4 data lines DL). Moreover, the number of redundant data lines RDL for each group G can vary (i.e., can be greater than 1).

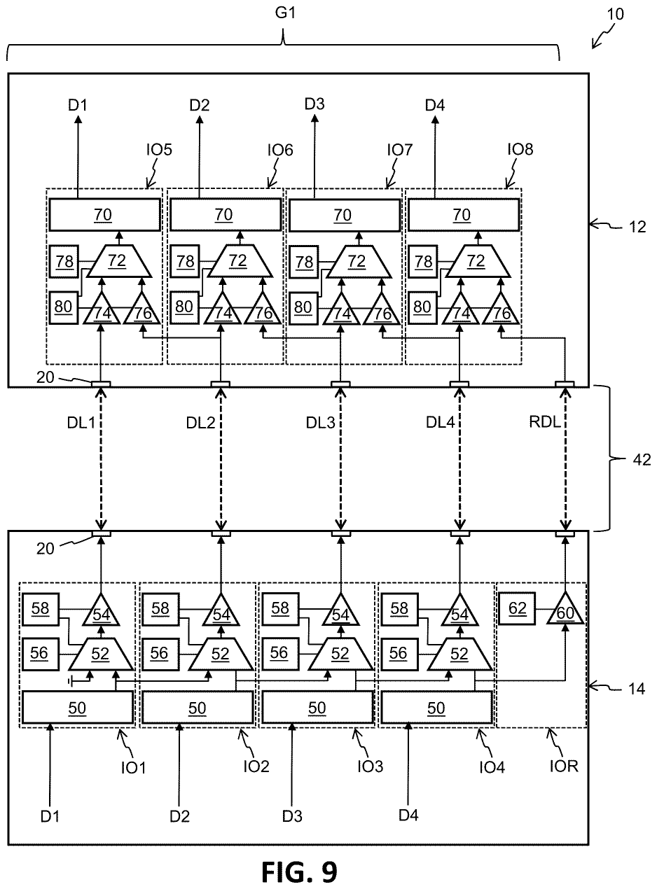

FIG. 9 illustrates an example of a configuration for the input/output modules IO for sending data from chiplet 14 to chiplet 12 that can utilize a redundant data line RDL when a data line DL is faulty. For the sending chiplet 14 (i.e., the chiplet sending the data in FIG. 9), each input/output module IO1-IO4 comprises circuitry includes a boundary scan cell 50, a multiplexer 52, an output buffer 54 connected to the respective data line DL, control circuitry 56 and power control circuitry 58. A redundant input/output module IOR comprises circuitry that includes an output buffer 60 connected to the redundant data line RDL, and control circuitry 62. The boundary scan cell 50 includes circuitry that receives the respective data (D1, D2, D3 or D4) to be sent from second chiplet 14 to first chiplet 12. The circuitry of boundary scan cell 50 provides the respective data to the multiplexer 52 in the respective input/output module, and to the multiplexer 52 of an adjacent input/output module IO. For example, the boundary scan cell 50 in input/output module IO1 provides data D1 to the multiplexer 52 in input/output module IO1 and to the multiplexer 52 in input/output module IO2. Similarly, the boundary scan cell 50 in input/output module IO2 provides data D2 to the multiplexer 52 in input/output module IO2 and to the multiplexer 52 in input/output module IO3. The boundary scan cell 50 in input/output module IO3 provides data D3 to the multiplexer 52 in input/output module IO3 and to the multiplexer 52 in input/output module IO4. The boundary scan cell 50 in input/output module IO4 provides data D4 to the multiplexer 52 in input/output module IO4 and to the output buffer 60 in redundant input/output module IOR.

The multiplexer 52 in each input/output module IO has two inputs for receiving data (a first input for receiving data received by that input/output module IO, and a second input for receiving data received by an adjacent input/output module IO). The control circuitry 56 dictates which data is output by the multiplexer 52 to the output buffer 54. The output buffer 54 outputs that data to the respective data line DL. The power control circuitry 58 provides operating power to the multiplexer 52 and output buffer 54.

For the receiving chiplet 12 (i.e., the chiplet receiving the data in FIG. 9), each input/output module IO5-IO8 in chiplet 12 includes circuitry that includes a boundary scan cell 70, a multiplexer 72, a first input buffer 74 connected to the respective data line DL for that input/output module IO, a second input buffer 76 connected to the data line DL for an adjacent input/output module IO or the redundant data line RDL, control circuitry 78 and power control circuitry 80. The multiplexer 72 in each input/output module IO has two inputs for receiving data (a first input for receiving data from the first input buffer 74 that originated from the data line DL for that input/output module IO, and a second input for receiving data from the second input buffer 76 that originated from the data line DL for an adjacent input/output module IO or the redundant data line RDL). The control circuitry 78 dictates which data is output by the multiplexer 72 to the circuitry of boundary scan cell 70 which in turn outputs that data. The power control circuitry 80 provides operating power to the multiplexer 72, the first input buffer 74 and the second input buffer 76.

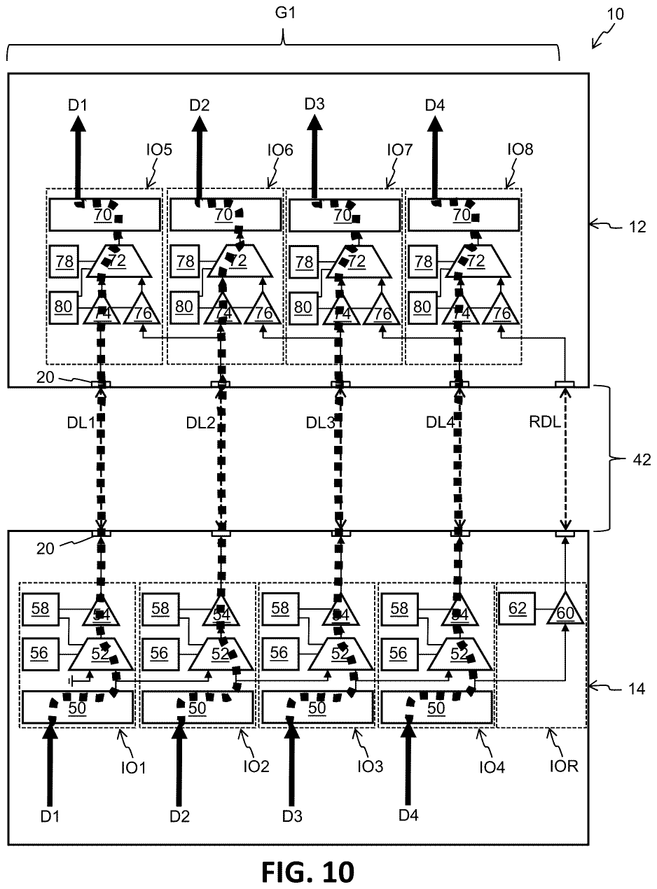

If none of the data lines DL are faulty, then for second chiplet 14 sending data, each multiplexer 52 outputs the data received on its first input (i.e., for the data received by the respective input/output module IO), and the redundant data line RDL is not used. For the example shown in FIG. 9, this would mean that data D1 is output by the multiplexer 52 of input/output module IO1, is passed through output buffer 54 and through data line DL1. Similarly, data D2 is output by the multiplexer 52 of input/output module IO2, is passed through output buffer 54 and through data line DL2, and so on. For the first chiplet 12 receiving the data, each multiplexer 72 outputs the data received on its first input (i.e., the data received by the respective data line DL for that input/output module IO), and the redundant data line RDL is not used. For the example shown in FIG. 9, this would mean that data D1 received by first input buffer 74 and by the first input of multiplexer 72 of input/output module IO5 is output by the multiplexer 72 and boundary scan cell 70 of input/output module IO5. Similarly, data D2 received by first input buffer 74 and by the first input of multiplexer 72 of input/output module IO6 is output by the multiplexer 72 and boundary scan cell 70 of input/output module IO6, and so on. The paths for data D1-D4 for the example where none of the data lines DL are faulty are illustrated in FIG. 10.

If one of the data lines DL is faulty, then for chiplet 14 sending the data, the various control circuitry 56 redirect data as necessary so that all the data is sent from chiplet 14 to chiplet 12 without using the faulty data line DL. For example, if data line DL2 is faulty (i.e., the example shown in FIG. 7), data D1 received by input/output module IO1 is processed by that module, whereby data D1 is received on the first input of multiplexer 52 of input/output module IO1, and is passed along to output buffer 54 and to data line DL1. Data D2 received by input/output module IO2 is sent to input/output module IO3, whereby data D2 is received by the second input of multiplexer 52 of input/output module IO3, and is passed along to output buffer 54 and to data line DL3. Data D3 received by input/output module IO3 is sent to input/output module IO4, whereby data D3 is received by the second input of multiplexer 52 of input/output module IO4, and is passed along to output buffer 54 and to data line DL4. Finally, data D4 received by input/output module IO4 is sent to the redundant input/output module IOR, whereby data D4 is received by the output buffer 60 of redundant input/output module IOR, and is passed along to redundant data line RDL. This data redirection results in no data being sent to faulty data line DL2. The power control circuitry 58 of input/output module IO2 can even deactivate the power to output buffer 54, multiplexer 52, or both, of input/output module IO2 to ensure no data signals reach faulty data line DL2.

Continuing with the example of data line DL2 being faulty, for chiplet 12 receiving the data, then the various control circuitry 78 redirect data as necessary so that all the data is received by chiplet 12 from chiplet 14 without using the faulty data line DL. For example, if data line DL2 is faulty (i.e., the example shown in FIG. 7), data D1 received on data line DL1 is processed and output by input/output module IO5, whereby data D1 is received by first input buffer 74, is sent to the first input of multiplexer 72 of input/output module IO5, and is passed along to boundary scan cell 70 and output from input/output module IO5. Data D2 received on data line DL3 is received by second input buffer 76 of input/output module IO6, is sent to the second input of multiplexer 72 of input/output module IO6, and is passed along to boundary scan cell 70 and output from input/output module IO6. Data D3 received on data line DL4 is received by second input buffer 76 of input/output module IO7, is sent to the second input of multiplexer 72 of input/output module IO7, and is passed along to boundary scan cell 70 and output from input/output module IO7. Finally, data D4 received on redundant data line RDL is received by second input buffer 76 of input/output module IO8, is sent to the second input of multiplexer 72 of input/output module IO8, and is passed along to boundary scan cell 70 and output from input/output module IO8. This data redirection results in no data being received from faulty data line DL2. The power control circuitry 80 of input/output module IO6 can even deactivate the power to first input buffer 74 of input/output module IO6 to ensure no data signals from faulty data line DL2 can reach further into the circuitry.

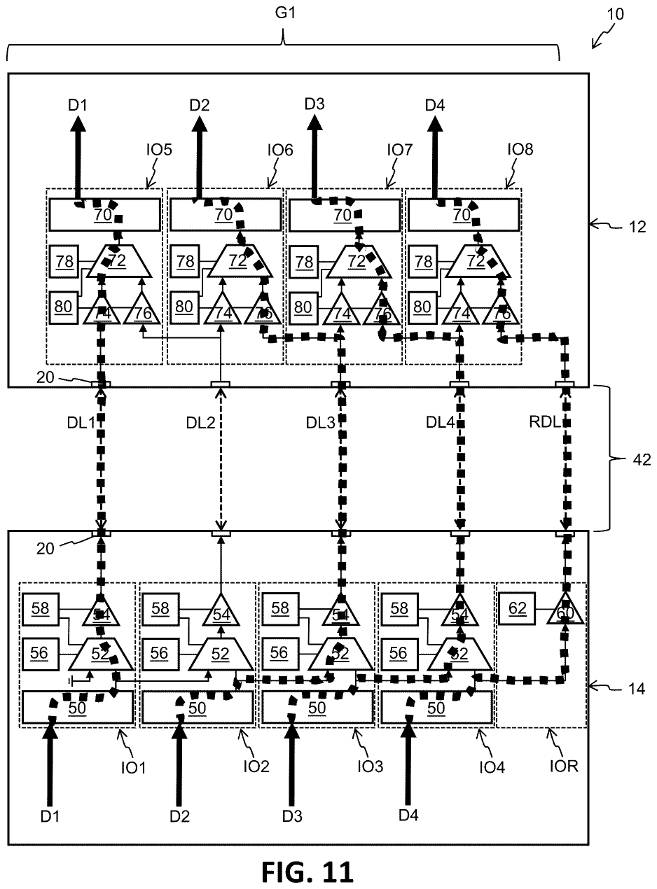

The paths for data D1-D4 for the example where data line DL2 is faulty are illustrated in FIG. 11. As shown in FIG. 11, data D1 is received by input/output module IO1, sent to data line DL1, and received by input/output module IO5. Data D2 is received by input/output module IO2, sent to input/output module IO3, sent to data line DL3, received by input/output module IO7, and sent to input/output module IO6. Data D3 is received by input/output module IO3, sent to input/output module IO4, sent to data line DL4, received by input/output module IO8, and sent to input/output module IO7. Data D4 is received by input/output module IO4, sent to redundant data line RDL via redundant input/output module IOR, and received by input/output module IO8.

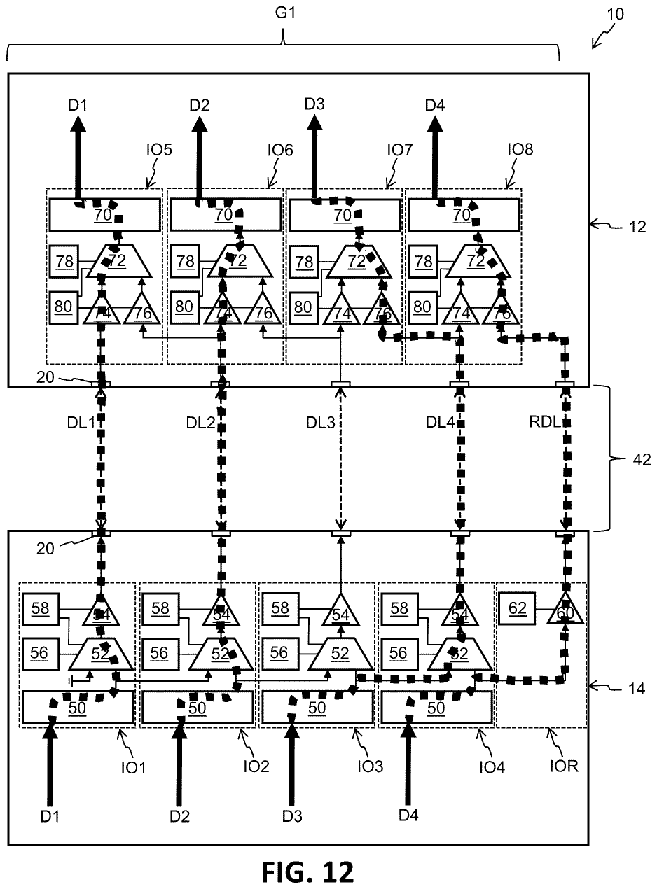

Similarly, the paths for data D1-D4 for an example where data line DL3 is faulty are illustrated in FIG. 12. Here, data D1 is sent along data line DL1, and data D2 is sent along data line DL2. Data D3 is received by input/output module IO3, sent to input/output module IO4, sent to data line DL4, received by input/output module IO8, and sent to input/output module IO7. Data D4 is received by input/output module IO4, sent to redundant data line RDL via redundant input/output module IOR, and received by input/output module IO8.

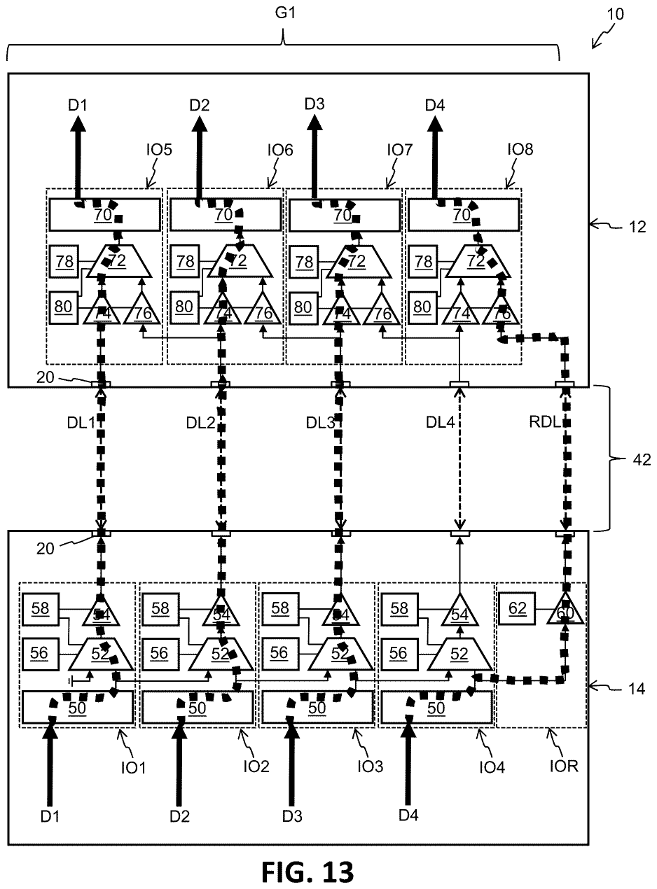

The paths for data D1-D4 for an example where data line DL4 is faulty are illustrated in FIG. 13. Here, data D1 is sent along data line DL1, data D2 is sent along data line DL2, and data D3 is sent along data line DL3. Data D4 is received by input/output module IO4, sent to redundant data line RDL via redundant input/output module IOR, and received by input/output module IO8.

While the example of FIG. 9 shows components for redirecting data being sent from chiplet 14 to chiplet 12 (i.e., data lines DL are unidirectional), components shown for each chiplet could be included in the other chiplet, making the data lines DL bidirectional. Alternately or additionally, some groups of data lines DL can be unidirectional from chiplet 14 to chiplet 12, while other groups of data lines DL can be unidirectional from chiplet 12 to chiplet 14. Further, while the example of FIG. 9 shows two chiplets 12, 14, more than two chiplets can be included in a single semiconductor device 10 with the data lines DL running between each of the chiplets.

The detection of faulty data lines DL can be performed by sending test data from chiplet 14 over each of the data lines DL, and determining if the test data is properly received by chiplet 12. The test data can be provided to or stored by boundary scan cells 50 of chiplet 14, which provide the test data to the first inputs of multiplexers 52 for transmission over the data lines DL. The test data received by chiplet 12 can be checked for accuracy by boundary scan cells 70 of chiplet 12. If a data line DL is found to be faulty, then the control circuitry 56 of the affected input/output modules IO of chiplet 14 are configured to redirect the data to be sent over the data lines DL as described above, and the control circuity 78 of the affected input/output modules IO of chiplet 12 are configured to redirect the data to be received from the data lines DL as described above.

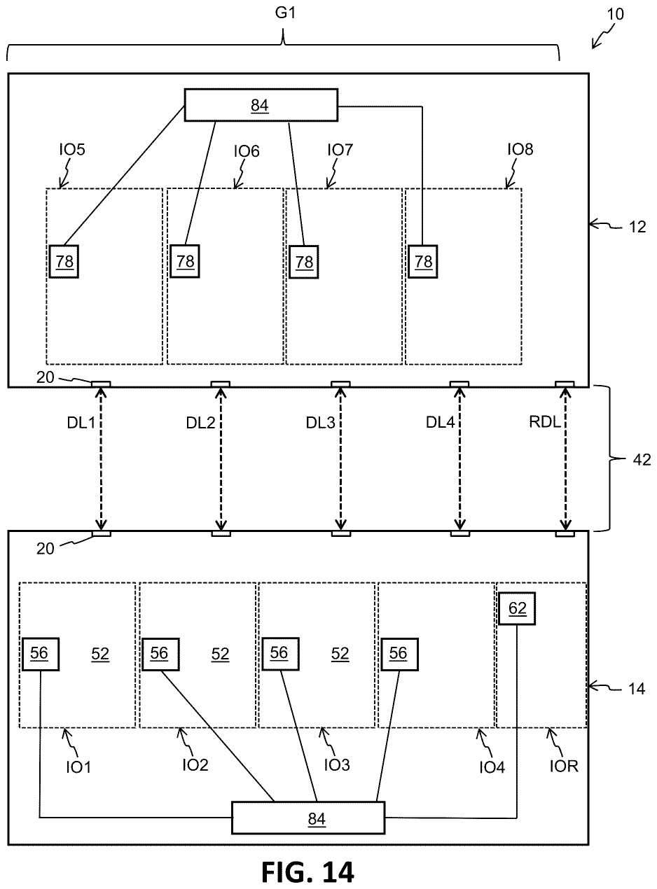

The operation of the control circuitry 56 of chiplet 14 and the control circuitry 78 of chiplet 12 for testing the data lines DL, and for redirecting data in the event of the faulty data line DL, can be controlled or coordinated by master control circuitry 84 located anywhere within semiconductor device 10 (e.g., in chiplet 12, in chiplet 14, in both chiplets 12 and 14 (as shown in FIG. 14, which is the same as FIG. 9 but with certain elements omitted for clarity), or in another chiplet within semiconductor device 10).

The semiconductor device 10 has many advantages. It detects a faulty data line DL for a group of data lines DL between chiplets, and utilizes a redundant data line RDL to effectively replace the faulty data line DL, thus avoiding discarding the entire semiconductor device 10 for being defective. Further, the data destined for the defective data line DL is sent over an adjacent data line DL, where data destined for that data line DL is sent over yet another adjacent data line DL, and so on, until data is sent over the redundant data line RDL. This configuration and technique means that there need not be a direct signal line between the redundant data line RDL or its input/output module, and the input/output modules IO for every data line DL in the group, thus reducing signal line complexity and excessive signal line lengths, especially where the number of data lines DL in the group is large.

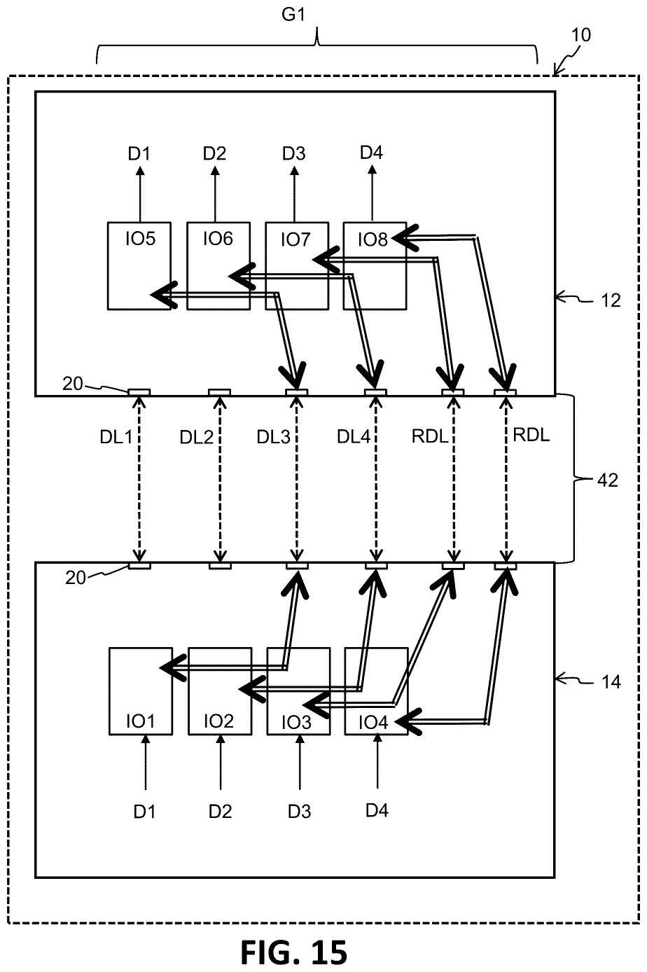

As stated above, the number of redundant data lines RDL for each group G can be more than 1. FIG. 15 illustrates an example where the group G1 includes two redundant data lines RDL, and an example of how data is rerouted when data lines DL1 and DL2 are both faulty. With this configuration, data D1 received by input/output module IO1 is rerouted to data line DL3, data D2 received by input/output module IO2 is rerouted to data line DL4, data D3 received by input/output module IO3 is rerouted to one of the redundant data lines RDL, and data D4 received by input/output module IO4 is rerouted to the other redundant data line RDL. The larger the number redundant data lines RDL per group G, the larger number of faulty data lines DL in the group G that can be effectively rerouted.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method operations need be performed in the exact order illustrated or claimed, but rather in any order (unless there is an explicitly recited limitation on any order) that allows the proper functioning of semiconductor device 10. It should be noted that reference herein to circuitry, or a module of circuitry, or the like, configured to perform an operation refers to the physical structure of the circuit (i.e., the capabilities of the circuitry as dictated by its structure), and does not refer to any method or actual use of the circuitry. Further, as used herein, the term “electrically coupled” includes “directly electrically coupled to” (no intermediate materials or elements there between that electrically connect the elements together) and “indirectly electrically coupled to” (intermediate materials or elements there between that electrically connect the elements together) unless otherwise indicated. Finally, the claims are comprising claims unless otherwise stated, and therefore “each” of a plurality of elements having a limitation does not preclude the inclusion of additional such elements lacking the limitation unless otherwise specifically claimed.

What is claimed is:

1. A semiconductor device, comprising:
a first chiplet;
a second chiplet;
an interface between the first chiplet and the second chiplet, wherein the interface comprises data lines and a redundant data line between the first chiplet and the second chiplet;
the second chiplet comprises a first input/output module and a second input/output module, wherein:
the first input/output module is electrically coupled to a first of the data lines and to the second input/output module, and the first input/output module is configured to receive first data and to send the first data to the second input/output module, and
the second input/output module is electrically coupled to a second of the data lines and to the redundant data line, the second input/output module is configured to receive second data and to send the second data to the redundant data line, and to receive the first data from the first input/output module and to send the first data to the second of the data lines; and
the first chiplet comprises a third input/output module and a fourth input/output module, wherein:
the third input/output module is electrically coupled to the second of the data lines and to the redundant data line and to the fourth input/output module, the third input/output module is configured to receive the second data from the redundant data line, and to receive the first data from the second of the data lines and to send the first data to the fourth input/output module, and
the fourth input/output module is electrically coupled to the first of the data lines, and the fourth input/output module is configured to receive the first data from the third input/output module.

2. The semiconductor device of claim 1, wherein the interface comprises:
contact pads at a surface of the first chiplet; and
contact pads at a surface of the second chiplet.

3. The semiconductor device of claim 2, wherein the interface comprises:
insulation material; and
conductive wiring extending through the insulation material and electrically connecting respective ones of the contact pads at the surface of the first chiplet to respective ones of the contact pads at the surface of the second chiplet.

4. The semiconductor device of claim 2, wherein the interface comprises:
a silicon substrate; and
electrical contacts extending through the silicon substrate and electrically connecting respective ones of the contact pads at the surface of the first chiplet to respective ones of the contact pads at the surface of the second chiplet.

5. The semiconductor device of claim 2, wherein the contact pads at the surface of the first chiplet are in physical contact with the contact pads at the surface of the second chiplet.

6. The semiconductor device of claim 1, wherein:
the second chiplet comprises a fifth input/output module and the first chiplet comprises a sixth input/output module;
the fifth input/output module is electrically coupled to a third of the data lines and to the first input/output module, and the fifth input/output module is configured to receive third data and to send the third data to the third of the data lines; and
the sixth input/output module is electrically coupled to the third of the data lines and to the fourth input/output module, and the sixth input/output module is configured to receive the third data from the third of the data lines.

7. The semiconductor device of claim 1, wherein:
the second chiplet comprises a fifth input/output module and the first chiplet comprises a sixth input/output module;
the fifth input/output module is electrically coupled to a third of the data lines and to the first input/output module, and the fifth input/output module is configured to receive third data and to send the third data to the first input/output module;
the first input/output module is configured to receive the third data from the fifth input/output module and to send the third data to the first of the data lines;
the fourth input/output module is electrically coupled to the sixth input/output module, and is configured to receive the third data from the first of the data lines and to send the third data to the sixth input/output module; and
the sixth input/output module is electrically coupled to the third of the data lines and is configured to receive the third data from the fourth input/output module.

8. A method of sending first data and second data in a semiconductor device that comprises:
a first chiplet;
a second chiplet;
an interface between the first chiplet and the second chiplet, wherein the interface comprises data lines and a redundant data line between the first chiplet and the second chiplet;
the second chiplet comprises a first input/output module and a second input/output module, wherein:
the first input/output module is electrically coupled to a first of the data lines and to the second input/output module, and
the second input/output module is electrically coupled to a second of the data lines and to the redundant data line;
the first chiplet comprises a third input/output module and a fourth input/output module, wherein:
the third input/output module is electrically coupled to the second of the data lines and to the redundant data line and to the fourth input/output module, and
the fourth input/output module is electrically coupled to the first of the data lines;
the method comprises:
receiving first data by the first input/output module;
sending the first data from the first input/output module to the second input/output module;
receiving the first data by the second input/output module;
sending the first data from the second input/output module to the second of the data lines;
receiving second data by the second input/output module;
sending the second data from the second input/output module to the redundant data line;
receiving the second data by the third input/output module from the redundant data line;
receiving the first data by the third input/output module from the second of the data lines; and
sending the first data from the third input/output module to the fourth input/output module.

9. The method of claim 8, wherein the interface comprises:
contact pads at a surface of the first chiplet; and
contact pads at a surface of the second chiplet.

10. The method of claim 9, wherein the interface comprises:
insulation material; and
conductive wiring extending through the insulation material and electrically connecting respective ones of the contact pads at the surface of the first chiplet to respective ones of the contact pads at the surface of the second chiplet.

11. The method of claim 9, wherein the interface comprises:
a silicon substrate; and
electrical contacts extending through the silicon substrate and electrically connecting respective ones of the contact pads at the surface of the first chiplet to respective ones of the contact pads at the surface of the second chiplet.

12. The method of claim 9, wherein the contact pads at the surface of the first chiplet are in physical contact with the contact pads at the surface of the second chiplet.

13. The method of claim 8, wherein:
the second chiplet comprises a fifth input/output module and the first chiplet comprises a sixth input/output module;
the fifth input/output module is electrically coupled to a third of the data lines and to the first input/output module; and
the sixth input/output module is electrically coupled to the third of the data lines and to the fourth input/output module;
the method comprising:
receiving third data by the fifth input/output module;
sending the third data from the fifth input/output module to the third of the data lines;
receiving the third data by the sixth input/output module from the third of the data lines.

14. The method of claim 8, wherein:
the second chiplet comprises a fifth input/output module and the first chiplet comprises a sixth input/output module;
the fifth input/output module is electrically coupled to a third of the data lines and to the first input/output module;
the fourth input/output module is electrically coupled to the sixth input/output module; and
the sixth input/output module is electrically coupled to the third of the data lines;
the method comprising:
receiving third data by the fifth input/output module;
sending the third data from the fifth input/output module to the first input/output module;
receiving the third data by the first input/output module;
sending the third data from the first input/output module to the first of the data lines;
receiving the third data by the fourth input/output module from the first of the data lines; and
sending the third data from the fourth input/output module to the sixth input/output module.
